(19) United States
(12) Patent Application Publication
(10) Pub. No.: US 2009/0074019 A1
(43) Pub. Date: Mar. 19, 2009

(54) OPTICAL INJECTION LOCKING OF VCSELS FOR WAVELENGTH DIVISION MULTIPLEXED PASSIVE OPTICAL NETWORKS (WDM-PONS)

(75) Inventors: Elaine Wong, Maribyrnong (AU); Connie Chang-Hasnain, Palo Alto, CA (US); Xiaoxue Zhao, Albany, CA (US)

Correspondence Address: JOHN P. O'BANION;O'BANION & RITCHEY LLP, 400 CAPITOL MALL SUITE 1550, SACRAMENTO, CA, 95814, US

(73) Assignee: THE REGENTS OF THE UNIVERSITY OF CALIFORNIA, Oakland, CA (US)

(21) Appl. No.: 12/204,215

(22) Filed: Sep. 4, 2008

Related U.S. Application Data
(63) Continuation of application No. PCT/US2007/063453, filed on Mar. 7, 2007.
(60) Provisional application No. 60/780,456, filed on Mar. 7, 2006.

(51) Int. Cl. H01S 5/183; H01S 5/06

(52) U.S. Cl. 372/26; 372/50.1; 372/20

(57) ABSTRACT

Low cost implementation of broadband upstream transmission for local and access network applications is made possible through the use of modulated downstream signals in a wavelength division multiplexed (WDM) passive optical network (PON) to injection-lock vertical-cavity surface-emitting lasers (VCSELs) for operation as stable, uncooled, and directly-modulated upstream transmitters. By way of example and not limitation, an optical network unit comprises: downstream input, photoreceiver, tunable laser, upstream output, and means for directionally coupling the downstream input into the tunable laser for modulating the output wavelength which is coupled to the upstream output.

### CROSS-REFERENCE TO RELATED APPLICATIONS

This application claims priority from, and is a 35 U.S.C. § 111 (a) continuation of, co-pending PCT international application Ser. No. PCT/US2007/063453, filed on Mar. 7, 2007, incorporated herein by reference in its entirety, which claims priority from U.S. provisional application Ser. No. 60/780,456, filed on Mar. 7, 2006, incorporated herein by reference in its entirety.

### STATEMENT REGARDING FEDERALLY SPONSORED RESEARCH OR DEVELOPMENT

This invention was made with Government support under Grant No. HR0011-04-0040 awarded by DARPA. The Government has certain rights in this invention.

### INCORPORATION-BY-REFERENCE OF MATERIAL SUBMITTED ON A COMPACT DISC

Not Applicable

### NOTICE OF MATERIAL SUBJECT TO COPYRIGHT PROTECTION

A portion of the material in this patent document is subject to copyright protection under the copyright laws of the United States and of other countries. The owner of the copyright rights has no objection to the facsimile reproduction by anyone of the patent document or the patent disclosure, as it appears in the United States Patent and Trademark Office publicly available file or records, but otherwise reserves all copyright rights whatsoever. The copyright owner does not hereby waive any of its rights to have this patent document maintained in secrecy, including without limitation its rights pursuant to 37 C.F.R. § 1.14.

### BACKGROUND OF THE INVENTION

1. Field of the Invention

This invention pertains generally to optical communications, and more particularly to injection-locked vertical-cavity surface-emitting lasers (VCSELs) for operation in directly-modulated optical network unit (ONU) transmitters.

2. Description of Related Art

The “access network” also known as the “first mile network”, connects the service provider central offices (COs) to businesses and residential subscribers. The bandwidth demand in the access network has been increasing rapidly over the past several years. Residential subscribers demand high bandwidth and offer media rich services. Similarly, corporate users demand broadband infrastructure through which they can connect their local area networks to the Internet backbone.

Passive optical networks (PONs) have been slowly evolving to provide substantially increased bandwidth in the access segment in comparison with currently deployed access solutions, such as digital subscriber line (DSL) and community antenna television (CATV). A PON has a point-to-multipoint topology where an optical line terminal (OLT) at the CO is connected to many optical network units (ONUs) through an optical power splitter. The ONUs can reside in houses, residential buildings and even commercial buildings giving rise to fiber-to-the-home (FTTH) and fiber-to-the-building (FTTB) broadband solutions. As more broadband applications appear, however, demands from end-users are expected to rapidly outgrow the capacity of first generation access networks. By employing (dense) wavelength division multiplexing (WDM), in which numerous wavelengths are supported in transporting data downstream to the users at the ONUs and upstream from the users to the CO, a number of benefits can be achieved, such as increasing capacity, simplifying upgrades, and guaranteeing security.

The deployment (D)WDM-PON has been hindered to date by the lack of any economical wavelength-specific optical transmitter at the ONU. The access network is particularly cost sensitive due to the relatively small number of end users it services. Research activities have therefore been focused towards achieving low-cost wavelength specific ONU transmitters. In a (D)WDM implementation, each ONU must emit a fixed wavelength for transmission that will not deviate too much from the allocated wavelength so that crosstalk with other wavelengths is minimized whilst ensuring minimal loss at the wavelength multiplexers and demultiplexers, such as arrayed waveguide gratings (AWGs). Wavelength specific sources, such as distributed feedback (DFB) lasers, distributed Bragg lasers, and tunable lasers are considered the most expensive types of ONU transmitters. In addition, these tunable devices require a wavelength monitoring circuit and a controller for each ONU for tuning the source to the required wavelength. Research activities have also been focused towards cost-effective “colorless” transmitters (e.g., spectrally-sliced light emitting diodes, injection-locked Fabry-Perot laser diodes, and wavelength-seeded reflective semiconductor optical amplifiers), in which the lasing wavelength of an ONU transmitter is determined externally by an injection light. Nonetheless, these solutions require additional centralized broadband light sources at the CO.

Accordingly, a need exists for a system and method of providing low-cost optical upstream transmission wavelength-locked to a downstream signal for use with local and access network applications. The present invention overcomes the deficiencies of previously developed upstream communications mechanisms.

### BRIEF SUMMARY OF THE INVENTION

The present invention generally comprises a novel configuration that exploits the use of a downstream optical wavelength for establishing upstream wavelength locking through an optical input tunable laser. A splitting means is configured for splitting a signal from a downstream signal and directionally coupling it into a tunable laser. The tunable laser accordingly generates an output wavelength responsive to the downstream signal. Output from the tunable laser is coupled into a directional coupling means whose output is directed into an upstream signal.

The invention is particularly well-suited for use with injection-locked vertical-cavity surface-emitting lasers (VCSELs), which allows implementation of an upstream signal link at low cost. Injection-locked VCSEL devices are configured to generate an output wavelength that is responsive to, typically matching, the injected wavelength.

The splitting means may comprise any optical coupling, or device, in which at least a second optical signal is split from a first optical signal.

The directional coupling means can comprise any non-reciprocal device for redirecting light and reducing back-reflection and back-scattering, such as an optical circulator. The term “optical circulator” is used herein in reference to any non-reciprocal device that redirect light at a given wavelength (or combination of wavelengths) from port-to-port in only one direction while reducing back reflection and back scattering in the reverse directions for any state of optical polarization.

In a preferred embodiment of the invention, an injection-locked vertical-cavity surface-emitting laser (VCSEL) is utilized as a stable, uncooled, and directly modulated optical network unit (ONU) transmitter. A plurality of the ONU units operating at different frequencies can be coupled to a given network. It should be appreciated that VCSELs can be grown expitaxially, which substantially reduces fabrication cost and makes “on-wafer testing” practical. Optical injection locking (OIL) has been demonstrated as an effective technique to greatly improve the modulation performance of a VCSEL as a laser transmitter in an optical communication network, specifically increasing the modulation efficiency and bandwidth while reducing laser noise, frequency chirp and nonlinear distortions (see, for example, Lukas Chrostowski, Xiaoxue Zhao, Connie J. Chang-Hasnain, “Microwave Performance of Optically Injection-Locked VCSELs”, IEEE Transactions on Microwave Theory and Techniques, Volume 54, Issue 2, Part 2, February 2006 Page(s):788-796, incorporated herein by reference in its entirety).

Accordingly, one aspect of the invention is an optical network unit for use in a wavelength division multiplexing passive optical network, comprising a VCSEL configured for injection locking by a downstream laser.

Another aspect of the invention is a wavelength division multiplexing passive optical network, comprising a plurality of optical network units wherein at least one of the optical network units comprises a VCSEL configured for injection locking by a downstream laser.

Another aspect of the invention is to improve a wavelength division multiplexing passive optical network having a plurality of optical network units where at least one of the optical network units has a VCSEL, by implementing the network with injection-locked VCSELs that are directly modulated by downstream lasers.

Another aspect of the invention is a transmitter for an optical network unit in a wavelength division multiplexing passive optical network, comprising an injection-locked VCSEL that is directly modulated by the injection light with modulation signals from a downstream laser.

In one embodiment, the downstream laser contains modulated signal for with downstream information. In one embodiment, the downstream laser is part of a wavelength division multiplexed system. In one embodiment, the VCSEL is directly modulated by its own current source which contains upstream information. In one embodiment, the downstream laser comprises a DFB laser. In one embodiment, the downstream laser comprises a VCSEL.

In one embodiment, the VCSEL is directly modulated by its own current source which contains upstream information, the VCSEL has a wavelength which is close to the downstream laser, and the downstream laser provides a modulated signal. In various embodiments, the VCSEL and downstream laser operate at are configured to operate at the same or different wavelengths, and the wavelengths are selected from the group consisting essentially of 850 nm, 1300 nm, 1550 nm or combinations thereof. In various embodiments, the VCSEL and downstream laser operate single mode, multi-mode, or combinations thereof (e.g., single-mode up and single-mode down; single-mode up and multi-mode down; multi-mode up and single-mode down;

and multi-mode up and multi-mode down). In one embodiment, the downstream laser is configured for low-level injection.

Another aspect of the invention is to provide for an injection-locked VCSEL to be used in passive optical networks (PON) to improve detectivity.

Another aspect of the invention is to provide for an injection-locked VCSEL to be used in WDM passive optical networks (PON) to improve wavelength locking and matching to grid.

Another aspect of the invention is to provide for transparency of injection-locking performance to the modulation of the master laser.

Another aspect of the invention is to provide an injection-locking scheme that is applicable to any VCSELs regardless of its lasing wavelength. For example, the injection-locking scheme may also be applied to 850 nm and 1330 nm VCSELs used in in-house communication multimode fiber links, provided that the DFB master laser and VCSEL have similar wavelengths.

The present invention promotes low-cost WDM-PON implementation as it eliminates the need for external broadband or narrowband light sources for injection locking, external modulators for modulation of upstream signals, and monitoring and temperature control circuits for wavelength stabilization. A number of additional benefits are provided by the directly-modulated injection-locked VCSELs as ONU transmitters in a WDM-PON of the present invention in which the injection-locking light is furnished by modulated downstream signals.

Further aspects of the invention will be brought out in the following portions of the specification, wherein the detailed description is for the purpose of fully disclosing preferred embodiments of the invention without placing limitations thereon.

### BRIEF DESCRIPTION OF THE SEVERAL VIEWS OF THE DRAWING(S)

The invention will be more fully understood by reference to the following drawings which are for illustrative purposes only:

FIG. 1 is a schematic of a (D)WDM-PON implementation with a plurality of optical network units (ONUs) having optically tuned lasers modulated by the downstream distributed feedback (DFB) lasers according to an embodiment of the present invention.

FIG. 2 is a schematic of an optical network unit (ONU) utilizing an injection-locked laser according to an embodiment of the present invention.

FIG. 3 is a schematic of an experimental setup utilized for testing the WDM-PONS system of FIG. 1, according to an aspect of the present invention.

FIGS. 4A-4D are stability graphs depicting various injection power and wavelength detuning values for: (A) CW master OIL, (B) 1.25 Gb/s modulated master OIL, (C) 2.5 Gb/s modulated master OIL, and (D) 10 Gb/s modulated master OIL.

FIG. 5 is a graph of optical spectra for a 2.5 Gb/s master DFB laser, free-running 2.5 Gb/s VCSEL, and injection-locked 2.5 Gb/s VCSEL.

FIG. 6 is a graph of bit-error-rate (BER) for downstream signals repeated for back-to-back (B2B) and transmission experiments, with respective eye diagrams at BER=10⁻⁹ shown as insets.

FIG. 7A-7B are graphs of bit-error-rate (BER) of upstream signals repeated for two injection power levels and three different downstream line-rates.

### DETAILED DESCRIPTION OF THE INVENTION

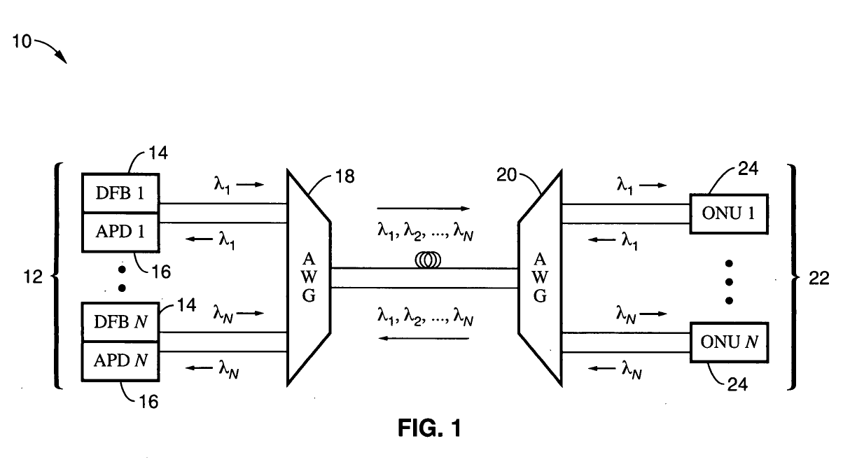

Referring more specifically to the drawings, for illustrative purposes the present invention is embodied in the apparatus generally shown in FIG. 1 through FIG. 7B. It will be appreciated that the apparatus may vary as to configuration and as to details of the parts, and that the method may vary as to the specific steps and sequence, without departing from the basic concepts as disclosed herein.

FIG. 1 illustrates an embodiment 10 of a deployment wavelength division multiplexing in an optical network, and more preferably in a passive optical network, or (D)WDM-PON, implementing VCSELs injection-locked by modulated downstream distributed feedback (DFB) lasers. At a central office (CO) a plurality of optical units 12 is shown configured with DFB lasers 14 either directly or externally modulated with downstream data. Optical receivers 16 may be implemented as avalanche photodiodes (AFD) or other means for registering data from the optical signal. DFB lasers 14 are temperature-tuned to emit distinct wavelengths that coincide with that of a multiplexer (AWG) 18. The modulated downstream signals from a DFB can traverse approximately 20 km or longer fiber before being demultiplexed at a second AWG 20. Each demultiplexed modulated downstream signal is then input to a plurality 22 of optical network units (ONU) 24.

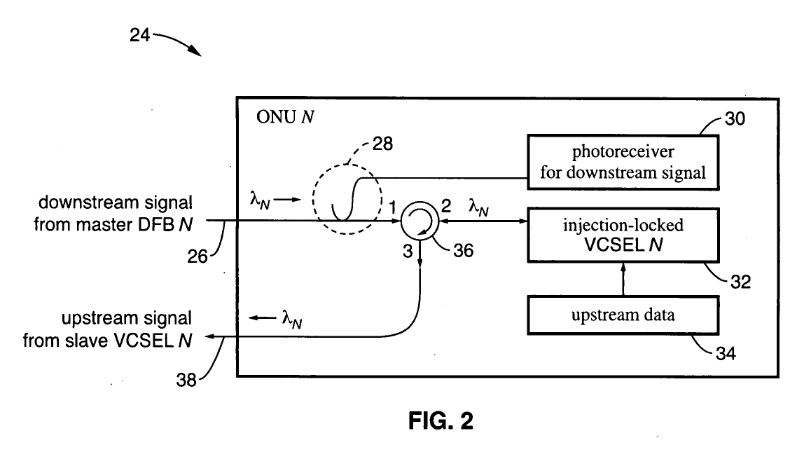

FIG. 2 illustrates an ONU 24 embodiment which splits the optical power of downstream signal 26 at splitting means 28 between a downstream photoreceiver 30 and an optical input tunable laser, such as an injection-locked vertical cavity surface emitting laser (VCSEL) 32. The tunable laser outputs an optical signal in response to receiving upstream data 34. To simplify description, the optical tunable laser will be generally referred to hereafter in its preferred form as an injection-locked VCSEL, which may be referred to simply as VCSEL. Downstream data is received by injection-locked VCSEL 32 in response to passing through a directional coupling means, such as an optical circulator 36 (i.e., port 1 to port 2). The splitting ratio of splitting means 28 is preferably chosen so that the downstream power level is above the sensitivity level of a downstream photoreceiver 30, yet sufficiently high to injection-lock VCSEL 32. Output from another port (i.e., port 3) of optical circulator 36 is the upstream signal 38 from slave injection-locked VCSEL.

In a typical configuration of an injection-locked VCSEL transmitter a continuous-wave (CW) master laser is used to lock the directly-modulated slave VCSEL. Injection-locking is described in the following article: Lukas Chrostowski, Xiaoxue Zhao, Connie J. Chang-Hasnain, “Microwave Performance of Optically Injection-Locked VCSELs”, IEEE Transactions on

Microwave Theory and Techniques, Volume 54, Issue 2, Part 2, February 2006 Page(s):788-796, and the references therein, each of which is incorporated herein by reference in its entirety. In this configuration the wavelength of the slave laser will match that of the master, which is temperature-controlled, thus resulting in accurate control of the slave VCSEL side in response to uncooled operation.

This configuration differs from previously proposed injection-locked VCSEL schemes in that the master laser is a modulated signal under relatively low injection power conditions. For example, assuming that each DFB laser outputs +5 dBm of optical power and a worst case 20 dB system loss, the injection power at port 2 of the optical circulator incident on the VCSEL is approximately −15 dBm. However, as will be shown later, the modulated signal of the master is neglected by the VCSEL and only the carrier frequency; that is, the central wavelength of the master laser, is registered by the VCSEL as the wavelength to lock onto. This point is significant for in this invention the master laser carries the downstream signal, while also serving a second function to lock the ONU slave laser onto a (D)WDM grid. The upstream signal is independent of the downstream signal, and since the slave VCSEL only respond to the master wavelength but not the downstream data, this makes it useful as a transmitter for upstream.

The injection-locked VCSEL 32 is then directly modulated with upstream data 34 which is transmitted back upstream to the CO through port 3 of optical circulator 36. Observe that since the modulated master DFB laser and the slave VCSEL laser have the same wavelength, the influence of Rayleigh backscattering of the master laser may result in performance degradation at the receiver of the upstream signal at the CO. To reduce the impact on upstream error rates, unidirectional fibers can be implemented, one for each direction of transmission, across the entire WDM-PON. The modulated upstream data can be coupled into another AWG, or the same AWG, to reduce cost.

It should be appreciated that the injection-locking scheme of the present invention can be applied to VCSELs of any wavelength including 850 nm and 1330 nm VCSELs, such as utilized for in-house communication multimode fiber links, insofar as the DFB master laser and VCSEL are of similar wavelengths.

One substantial advantage of this inventive system is that with the use of optical injection locking (OIL), the slave lasers are automatically wavelength matched to the DWDM grid and lock onto the specific AWG port provided by the CO, without requiring any additional wavelength locking or stabilizing elements or equipment. This wavelength matching ability expands the wavelength tolerance of the ONU and fosters compatibility with various vendors and systems configured with slightly different DWDM grids. This flexibility and compatibility makes the OIL-VCSEL of the present invention particularly well-suited for use in broadband low-cost DWDM-PON implementations.

As the downstream (master) laser power is at a low intensity when it reaches ONU 24, the wavelength range that would lock the slave laser is reduced, as seen in the next section. The slave laser emission wavelength is typically dependent on its bias current or heat sink temperature. A method according to the invention can be implemented with a “training” session which includes a step of finding the lockable wavelength regime. By way of example and not limitation, the training may be performed utilizing a look-up table, by forming a feedback loop with measurements of the slave laser reflected power through port 3 (FIG. 2) or its junction voltage while sweeping the slave VCSEL wavelength. It is preferred that the training session be executed when the ONU is started up, or infrequently as necessary, in a similar manner as one may execute the rebooting of a personal computer.

### EXAMPLE

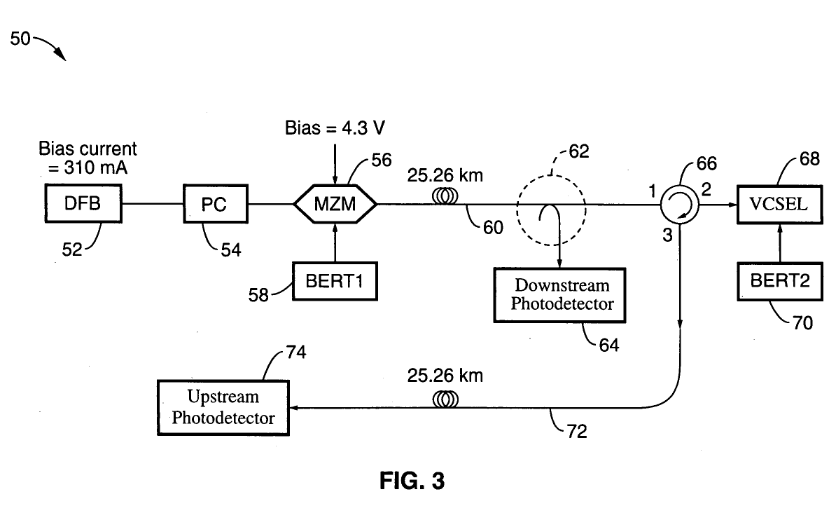

FIG. 3 illustrates an experimental setup 50 utilized to test aspects of the present invention. At the optical line terminal (OLT) continuous-wave (CW) light from a DFB laser 52 (i.e., biased at 310 mA) is shown passing through polarization controller 54 and then being externally modulated at modulator 56, such as a Mach-Zehnder modulator (MZM). In the case depicted, a first bit-error-rate test set (BERT1) 58 is utilized, such as with a 2²³-1 pseudorandom bit sequence (PRBS) with non-return to zero (NRZ) data.

The modulated downstream signal is either connected directly to a 3 dB coupler 62 for back-to-back (B2B) measurements, or through a fiber length 60 (shown as 25.26 km) of single mode fiber for transmission experiments to 3 dB coupler 62. The output of the 3 dB coupler is shown connected to a downstream photodetector 64, while fiber 60 connects to a port (i.e., port 1) of an optical circulator 66 from which the modulated downstream signal is fed towards a VCSEL 68 via another port (i.e., port 2) of optical circulator 66.

By way of example and not limitation, the VCSEL used in these tests was a conventional 1.55 μm VCSEL, having a sub-milliampere threshold current of 0.5 mA and ˜2 mW (3 dBm) maximum output power. For testing purposes, the VCSEL is shown coupled to a second bit-error-rate test set (BERT 2) 70. BERT2 is set to provide an optimal biasing condition of 5 mA and direct modulation of the VCSEL with a 2.5 Gb/s 2²³-1 PRBS NRZ data. The VCSEL is free-space coupled to the fiber connected to another port (i.e., port 2) of the optical circulator, incurring a 6 to 10 dB coupling power loss. The optical output of the VCSEL at CW measured at the output port (i.e., port 3) of circulator 66 is ˜−9.5 dBm. Output from the circulator is shown directed through a length of fiber 72 toward upstream photodetector 74. In a practical network, lower coupling losses can be easily achieved by deploying packaged VCSELs with a more sophisticated design or structure, such as lensed fiber. The upstream signal from the VCSEL is detected, such as by utilizing a 2.5 GHz APD receiver.

Although this example was performed at a wavelength of 1.55 μm, as previously mentioned, the novel configuration is applicable to other wavelengths; in particular, it is well suited for 0.85 μm or 1.3 μm wavelengths applications. In addition, the same configuration also applies to multi-mode VCSELs.

Two important parameters, injection power and wavelength detuning, forming the stability plot were used to characterize the robustness of frequency locking. Detuning is defined according to the present invention as the downstream master DFB laser wavelength minus the free-running slave VCSEL wavelength. The wavelength detuning and injection power was adjusted by tuning the master DFB laser temperature and utilizing optical attenuators, respectively.

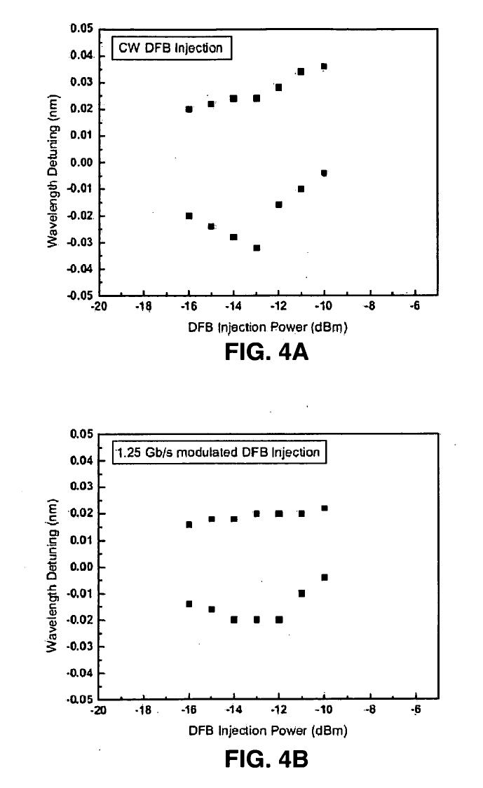

FIG. 4A-4D illustrate the effect of wavelength detuning and injection power on the locking stability for various master DFB laser line-rates, i.e., CW, 1.25 Gb/s, 2.5 Gb/s and 10 Gb/s respectively. The measurements were obtained using an optical spectrum analyzer placed at a port (i.e., port 3) of the optical circulator. FIG. 4A illustrates a stability plot for the condition when both slave and the master lasers are continuous-wave (CW).

The locking range decreases with increasing master laser line-rate, as indicated by FIG. 4B-4D. During testing it was also observed that the locking range decreases even further when the slave laser is modulated, with the worst case arising when both slave and master lasers are modulated at the same line-rate. It was also noted that while a high injection power is expected to yield a large and stable locking range, the results indicate a decreasing locking range and hence decreased stability with increasing optical power above −13 dBm. This can be attributed to the fact that in the present configuration, the master is being modulated and hence a higher injection power will mean a higher modulation signal. The higher modulation signal leads to a degradation of the locking stability, and thus results in a smaller locking range. In contrast, for low injection power levels, the locking range also decreases and this is due to insufficient power to injection-lock the VCSEL. An optimal point of injection power was noticed in the cases tested in which the largest locking range was obtained and thus an stability maximized.

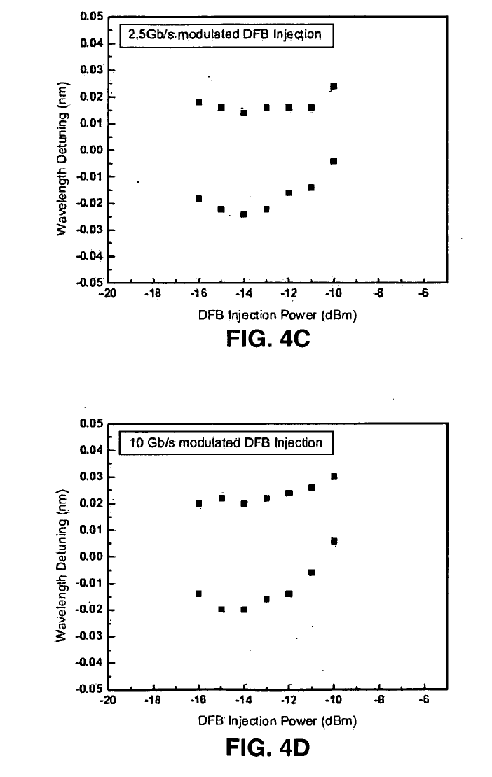

FIG. 5 illustrates the optical spectra of the 2.5 Gb/s modulated master DFB laser, 2.5 Gb/s free-running VCSEL, and superimposed injection-locked 2.5 Gb/s VCSEL. The optical spectrum of the injection-locked 2.5 Gb/s

VCSEL is narrower in linewidth as compared to that of the 2.5 Gb/s free-running VCSEL, and is shifted to a slightly longer wavelength, matching that of the master DFB laser. The injection-locked optical spectrum indicates that beneficial injection-locking performance was obtained even though the master DFB laser was modulated at 2.5 Gb/s with an injection power of −15 dBm for a worst case performance.

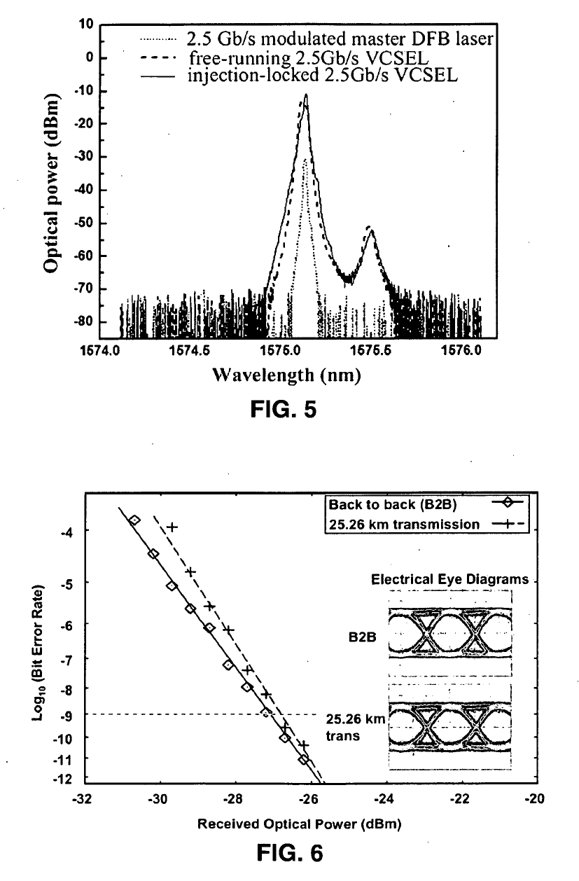

FIG. 6 illustrates BER measurements for a setup in which a 2.5 GHz APD receiver is used to detect the 2.5 Gb/s downstream signals connected to an output of 3 dB coupler 62 (FIG. 3). The measurements were first taken for a back-to-back (B2B) experiment and then repeated for the 25.26 km transmission fiber. The graphs indicate a minimal power penalty at BER=10⁻⁹. An inset shows eye diagrams for both the B2B and 25.26 km fiber configurations at BER=10⁻⁹.

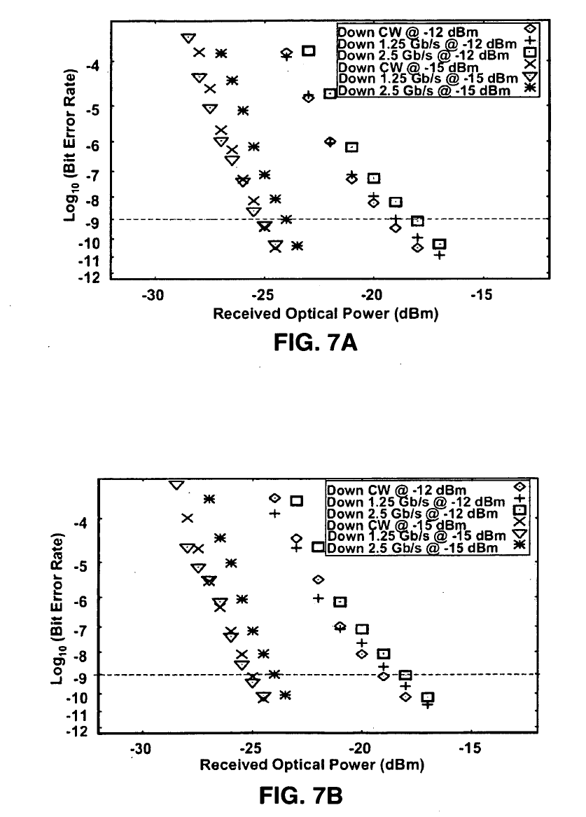

FIG. 7A-7B illustrate bit-error-rates (BER) for two injection power levels. The performance dependence of the injection power and line-rate of the master DFB laser was studied for the directly-modulated injection-locked VCSEL. The upstream BER curves were measured for two injection power levels (i.e., −12 dBm and −15 dBm) and three master DFB laser line-rates (i.e., CW, 1.25 Gb/s, and 2.5 Gb/s) which are plotted on FIGS. 7A and 7B, respectively, for the back-to-back and 25.26 km transmission tests, respectively. Both sets of BER curves show similar trends with minimal penalty between the back-to-back and the transmission case. Overall, the results indicate that performance improves with lower injection power levels and lower line-rates. At the higher injection power level (−12 dBm), both sets of BER curves show signs of an onset of an error floor. Nevertheless, error-free performance (BER=10⁻⁹) can still be achieved under all practical conditions considered, while typical injection power levels were approximately −15 dBm, as discussed above.

As can be seen, therefore, the present invention is a novel WDM-PON implementation that uses modulated downstream signals to injection-lock VCSELs such that the VCSEL can function as stable, uncooled, and directly-modulated ONU transmitters. The invention is particularly well-suited for low-cost implementation of upstream optical transmission. Test results illustrate the feasibility of the present invention while highlighting the performance dependency on injection power and the line-rate of the modulated downstream signal. The present invention eliminates costly components, such as external broadband or narrowband light sources for injection locking, external modulators for modulation of upstream signals, and both monitoring and temperature control circuits for wavelength stabilization.

Although the description above contains many details, these should not be construed as limiting the scope of the invention but as merely providing illustrations of some of the presently preferred embodiments of this invention. Therefore, it will be appreciated that the scope of the present invention fully encompasses other embodiments which may become obvious to those skilled in the art, and that the scope of the present invention is accordingly to be limited by nothing other than the appended claims, in which reference to an element in the singular is not intended to mean “one and only one” unless explicitly so stated, but rather “one or more.” All structural, and functional equivalents to the elements of the above-described preferred embodiment that are known to those of ordinary skill in the art are expressly incorporated herein by reference and are intended to be encompassed by the present claims. Moreover, it is not necessary for a device or method to address each and every problem sought to be solved by the present invention, for it to be encompassed by the present claims. Furthermore, no element, component, or method step in the present disclosure is intended to be dedicated to the public regardless of whether the element, component, or method step is explicitly recited in the claims. No claim element herein is to be construed under the provisions of 35 U.S.C. 112, sixth paragraph, unless the element is expressly recited using the phrase “means for.”

What is claimed is:

1. An optical network unit for use in a passive optical network, comprising:
a VCSEL configured for injection locking by a downstream laser.

2. An optical network unit as recited in claim 1:
wherein the downstream laser contains a modulated signal with downstream information.

3. An optical network unit as recited in claim 1:
wherein the downstream laser is part of a wavelength division multiplexed system.

4. An optical network unit as recited in claim 1:
wherein said VCSEL is directly modulated by its own current source which contains upstream information.

5. An optical network unit as recited in claim 1, wherein said downstream laser comprises a DFB laser.

6. An optical network unit as recited in claim 1, wherein said downstream laser comprises a VCSEL.

7. An optical network unit as recited in claim 1:
wherein said VCSEL is directly modulated by its own current source which contains upstream information;
wherein said VCSEL has a wavelength which is close to the downstream laser; and
wherein the downstream laser provides a modulated signal.

8. An optical network unit as recited in claim 1, wherein said VCSEL and said downstream laser are configured to operate at the same wavelengths.

9. An optical network unit as recited in claim 1, wherein said VCSEL and said downstream laser are configured to operate at different wavelengths.

10. An optical network unit as recited in claim 1, wherein said VCSEL and said downstream laser are configured to operate at wavelengths selected from the group consisting essentially of 850 nm, 1300 nm, 1550 nm.

11. An optical network unit as recited in claim 1, wherein said VCSEL and said downstream laser are configured to operate single mode, multi-mode, or a combination thereof.

12. An optical network unit as recited in claim 1, wherein said downstream laser is configured for low-level injection.

13. A wavelength division multiplexing passive optical network, comprising:
a plurality of optical network units; and
at least one said optical network unit comprising a VCSEL configured for injection locking by a downstream laser.

14. A wavelength division multiplexing passive optical network as recited in claim 13, wherein the downstream laser contains a modulated signal with downstream information.

15. A wavelength division multiplexing passive optical network as recited in claim 13, wherein said VCSEL is directly modulated by its own current source which contains upstream information.

16. A wavelength division multiplexing passive optical network as recited in claim 13, wherein said downstream laser comprises a DFB laser.

17. A wavelength division multiplexing passive optical network as recited in claim 13, wherein said downstream laser comprises a VCSEL.

18. A wavelength division multiplexing passive optical network as recited in claim 13:
wherein said VCSEL is directly modulated by its own current source which contains upstream information;
wherein said VCSEL has a wavelength which is close to the downstream laser; and
wherein the downstream laser provides a modulated signal.

19. A wavelength division multiplexing passive optical network as recited in claim 13, wherein said VCSEL and said downstream laser are configured to operate at the same wavelengths.

20. A wavelength division multiplexing passive optical network as recited in claim 13, wherein said VCSEL and said downstream laser are configured to operate at different wavelengths.

21. A wavelength division multiplexing passive optical network as recited in claim 13, wherein said VCSEL and said downstream laser are configured to operate at wavelengths selected from the group consisting essentially of 850 nm, 1300 nm, 1550 nm.

22. A wavelength division multiplexing passive optical network as recited in claim 13, wherein said VCSEL and said downstream laser are configured to operate single mode, multi-mode, or a combination thereof.

23. A wavelength division multiplexing passive optical network as recited in claim 13, wherein said downstream laser is configured for low-level injection.

24. In a wavelength division multiplexing passive optical network having a plurality of optical network units, at least one said optical network unit having a VCSEL, the improvement comprising:
injection-locking said VCSEL by a downstream laser.

25. An improvement as recited in claim 24:
wherein the downstream laser contains a modulated signal with downstream information.

26. An improvement as recited in claim 24:
wherein said VCSEL is directly modulated by its own current source which contains upstream information.

27. An improvement as recited in claim 24, wherein said downstream laser comprises a DFB laser.

28. An improvement as recited in claim 24, wherein said downstream laser comprises a VCSEL.

29. An improvement as recited in claim 24:
wherein said VCSEL is directly modulated by its own current source which contains upstream information;
wherein said VCSEL has a wavelength which is close to the downstream laser; and
wherein the downstream laser provides a modulated signal.

30. An improvement as recited in claim 24, wherein said VCSEL and said downstream laser are configured to operate at the same wavelengths.

31. An improvement as recited in claim 24, wherein said VCSEL and said downstream laser are configured to operate at different wavelengths.

32. An improvement as recited in claim 24, wherein said VCSEL and said downstream laser are configured to operate at wavelengths selected from the group consisting essentially of 850 nm, 1300 nm, 1550 nm.

33. An improvement as recited in claim 24, wherein said VCSEL and said downstream laser are configured to operate single mode, multi-mode, or a combination thereof.

34. An improvement as recited in claim 24, wherein said downstream laser is configured for low-level injection.

35. A transmitter for an optical network unit in a wavelength division multiplexing passive optical network, comprising:
a VCSEL configured for injection locking by a downstream laser.

36. A transmitter as recited in claim 35:
wherein the downstream laser contains a modulated signal with downstream information.

37. A transmitter as recited in claim 35, wherein the downstream laser is part of a wavelength division multiplexed system.

38. A transmitter as recited in claim 35, wherein said VCSEL is directly modulated by its own current source which contains upstream information.

39. A transmitter as recited in claim 35, wherein said downstream laser comprises a DFB laser.

40. A transmitter as recited in claim 35, wherein said downstream laser comprises a VCSEL.

41. A transmitter as recited in claim 35:
wherein said VCSEL is directly modulated by its own current source which contains upstream information;
wherein said VCSEL has a wavelength which is close to the downstream laser; and
wherein the downstream laser provides a modulated signal.

42. A transmitter as recited in claim 35, wherein said VCSEL and said downstream laser are configured to operate at the same wavelengths.

43. A transmitter as recited in claim 35, wherein said VCSEL and said downstream laser are configured to operate at different wavelengths.

44. A transmitter as recited in claim 35, wherein said VCSEL and said downstream laser are configured to operate at wavelengths selected from the group consisting essentially of 850 nm, 1300 nm, 1550 nm.

45. A transmitter as recited in claim 35, wherein said VCSEL and said downstream laser are configured to operate single mode, multi-mode, or combination thereof.

46. A transmitter as recited in claim 35, wherein said downstream laser is configured for low-level injection.

47. An optical network unit, comprising:
an optical downstream input;
a photoreceiver configured for receiving and registering data from said optical downstream input;
an optical input tunable laser;
an optical upstream output; and
means for directionally coupling at least a portion of said optical downstream input into said optical input tunable laser for modulating the optical wavelength generated by said optical input tunable laser in response to said optical downstream input, and for directionally coupling an output from said optical input tunable laser into said optical upstream signal.

48. An optical network unit as recited in claim 47, wherein said tunable laser comprises a tunable laser diode.

49. An optical network unit as recited in claim 48, wherein said tunable laser diode comprises a vertical-cavity surface-emitting laser (VCSEL).

50. An optical network unit as recited in claim 47, wherein said tunable laser comprises an injection-locked vertical-cavity surface-emitting lasers (VCSEL).

51. An optical network unit as recited in claim 47, wherein said means for directionally coupling comprises an optical circulator coupled between said optical downstream input, said optical input tunable laser, and said optical upstream output.

52. An optical network unit as recited in claim 47, further comprising an optical coupling for splitting the signal from said optical downstream input to said photoreceiver and said means for directional coupling.

53. An optical network unit as recited in claim 47, wherein the output wavelength of said optical input tunable laser is matched to the wavelength of said optical downstream input in response to receiving the wavelength of said optical downstream input through said directional optical coupling means at said optical input tunable laser.

54. An optical network unit as recited in claim 47, wherein said optical input tunable laser is configured to modulate the wavelength of its optical output in response to the central wavelength of the optical downstream input, and to ignore the modulated signal carried in said optical downstream input.

55. An optical network unit as recited in claim 47, wherein said optical network unit (ONU) is configured for connection to an optical multiplexer/demultiplexer to which a plurality of ONUs can be connected.
